(19) United States
(12) Patent Application Publication
(10) Pub. No.: US 2020/0066567 A1
(43) Pub. Date: Feb. 27, 2020

(54) PROCESSING OF PLASTICS FILM COMPONENTS FOR DISPLAY AND/OR SENSOR DEVICES

(71) Applicant: FLEXENABLE LIMITED, Cambridge (GB)

(72) Inventor: Sharjil SIDDIQUE, Cambridge (GB)

(73) Assignee: FLEXENABLE LIMITED, Cambridge (GB)

(21) Appl. No.: 16/548,986

(22) Filed: Aug. 23, 2019

(30) Foreign Application Priority Data
Aug. 24, 2018 (GB) 1813844.6

(51) Int. Cl. H01L 21/683; H01L 27/32

(52) U.S. Cl. CPC H01L 21/6835; H01L 27/3274; H01L 21/6838

(57) ABSTRACT

A technique comprising: preparing a self-supporting plastics film component comprising a plastics support film supporting at least a stack of layers defining an array of pixel electrodes and electrical circuitry for independently addressing each pixel electrode via conductors outside the array of pixel electrodes; thereafter attaching a carrier to the plastics film component; mounting the plastics film component via the carrier on a support unit surface defining a plurality of openings connected to a vacuum pump; and processing the plastics film component mounted on the support unit surface while operating the vacuum pump; and thereafter releasing the carrier from the plastics film component.

The production of display and sensor devices may involve the production of a self-supporting plastics film component comprising a support film supporting at least a stack of conductor, semiconductor and insulator layers defining an array of pixel electrodes and electrical circuitry for independently addressing each pixel electrode via conductors outside the array of pixel electrodes.

Further processing of the plastics film component may involve mounting the plastics film component on a support surface of a processing tool. Vacuum stages are used for some processing tools with the aim of securely holding the plastics film component in place for processing, while enabling easy and automated release of the plastics film component from the processing tool after the processing is finished.

The inventor for the present application has observed processing defects when using vacuum stages to process plastics film components for devices such as display devices or sensor devices comprising an array of pixel electrodes; and the inventor has had the idea of mounting the plastics film component on the vacuum stage via a temporary carrier temporarily attached to the plastics film component.

There is hereby provided a method comprising: preparing a self-supporting plastics film component comprising a plastics support film supporting at least a stack of layers defining an array of pixel electrodes and electrical circuitry for independently addressing each pixel electrode via conductors outside the array of pixel electrodes; thereafter attaching a carrier to the plastics film component; mounting the plastics film component via the carrier on a support unit surface defining a plurality of openings connected to a vacuum pump; and processing the plastics film component mounted on the support unit surface while operating the vacuum pump; and thereafter releasing the carrier from the plastics film component.

According to one embodiment, preparing the plastics film component comprises: forming at least part of the plastics film component by a process comprising attaching the support film via at least one layer of adhesive to another carrier; processing the support film in situ on the another carrier; and thereafter removing the support film from the another carrier.

According to one embodiment, processing the plastics film component comprises bonding a driver chip unit to the plastics film component, to create a conductive connection between an array of conductors of the plastics film component and a corresponding array of conductors of the driver chip unit.

According to one embodiment, the driver chip unit comprises a support film supporting said array of conductors of the driver chip unit, and at least one driver chip bonded to the support film with conductive connections between terminals of the driver chip and said array of conductors of the driver chip unit.

According to one embodiment, the carrier is more rigid than the plastics film component.

According to one embodiment, the carrier comprises a sheet of glass.

According to one embodiment, mounting the plastics film component on the vacuum stage comprises mounting the plastics film component such that an edge portion thereof extends beyond a lateral edge of the vacuum stage; and the processing comprises processing said edge portion of the plastics film component.

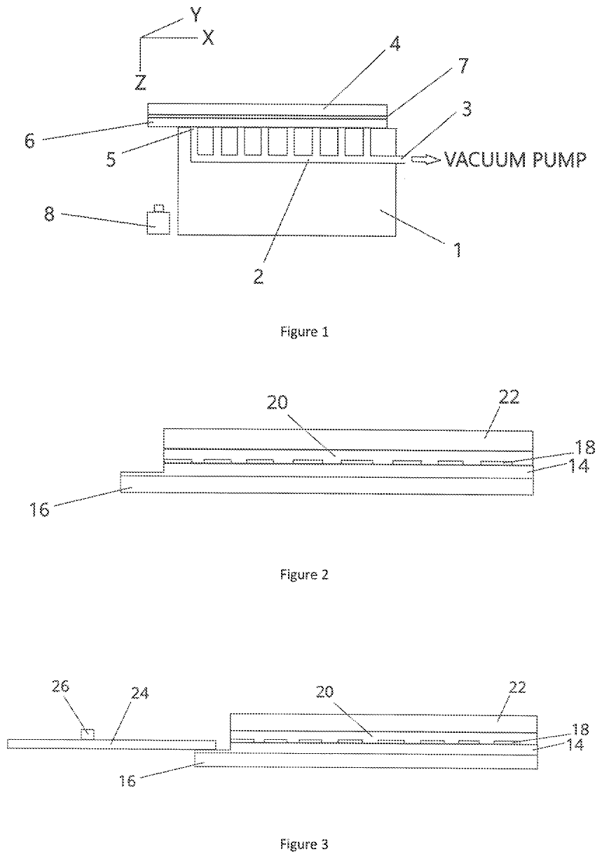

FIG. 1 illustrates a vacuum stage mounting process according to an embodiment of the present invention;

FIG. 2 illustrates one example of a plastics film component for processing using a vacuum stage mounting process as shown in FIG. 1;

FIG. 3 illustrates one example of the plastics film component of FIG. 2 after processing; and

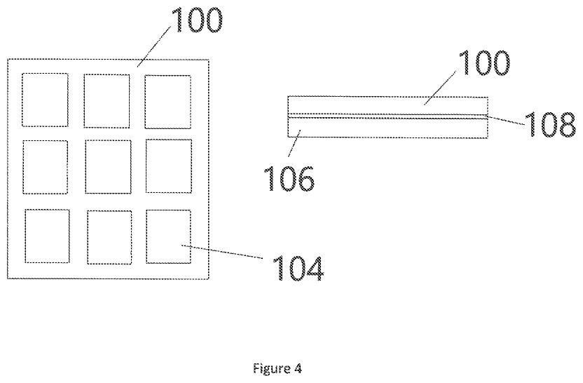

FIG. 4 illustrates the preparation of a plurality of individual plastics film components from processing of a larger area unit.

With reference to FIG. 1, an example of a process according to an embodiment of the invention involves the mounting of a plastics film component 4 for a display device and/or sensor device on a vacuum stage 1. The interior of the vacuum stage comprises one or more conduits 2 that terminate in openings 5 at the upper, mounting surface of the vacuum stage and are connected to one or more ports 3, to which a vacuum pump is connected.

The plastics film component 4 may, for example, have a thickness of no more than about 100 microns.

In this example, the plastics film component 4 is mounted on the mounting surface of the vacuum stage 1 so as to cover the openings 5, and with an edge portion to be processed extending beyond an edge of the vacuum stage 1. In this example, the plastics film component comprises at least one plastics support film supporting alignment marks on an upper surface of the support film (i.e. the surface of the support film remote from the mounting surface of the vacuum stage), which alignment marks are detectable through the support film from below. A detector 8 is positioned below this edge portion of the plastics film component 4 to detect the position of the alignment marks, and the detected X-Y position of the alignment marks via the detector is used to control the processing of the edge portion of the plastics film component 4.

Mounting the plastics film component 4 on the vacuum stage involves first attaching the plastics film component 4 to a temporary carrier 6, and then mounting the combination of plastics film component 4 and temporary carrier 6 to the vacuum stage, with the temporary carrier 6 between the plastics film component 4 and the vacuum stage 1. The temporary carrier 6 may, for example, comprise a single component carrier (such as e.g. a single sheet of glass) or a multi-component carrier such as a plastics sheet bonded to a glass sheet. In one example, the temporary carrier is more rigid than the plastics film component. In one example, the temporary carrier comprises a glass sheet having a thickness of greater than about 0.1 mm, or greater than about 0.5 mm.

The process of attaching the plastics film component 4 to the temporary carrier 6 will depend on the conditions of the processing to be carried out on the plastics film component 4. It is sufficient that the plastics film component 4 retains a fixed position relative to the temporary carrier 6 during the processing of the plastics film component 4. For some types of processing, it may be sufficient that the attachment arises solely from physical adhesion forces (Van der Waals bonds) between the plastics film component 4 and the temporary carrier 6, without requiring chemical bonds between the temporary carrier 6 and the plastics film component 4; and the temporary carrier may be provided with an upper surface coating 7 that generates better physical adhesion forces between the carrier 6 and the plastics film component 4.

In the example described below where the processing comprises ACF bonding, the attachment between the plastics film component 4 and the temporary carrier 6 uses adhesive tape comprising a layer of silicone pressure-sensitive adhesive between the plastics film component 4 and the temporary carrier 6. The adhesive tape exhibits a peel strength of about 0.06N in the standard test method ASTM D3330 for peel adhesion of pressure-sensitive tape, which involves measuring the average force value over a 50 mm (2″) length of peeling after the first 25 mm (1″) of peeling.

The processing of the edge portion may for example comprise ACF bonding between the conductors of e.g. a COF (chip-on-flex) unit or the terminals of a chip to an array of conductors of the plastics film component 4, which array of conductors are in a predetermined position relative to the above-mentioned alignment marks of the plastics film component. However, the technique is equally applicable to other kinds of processing.

After processing is completed, the temporary carrier 6 is released from the plastics film component 4. In one example, the plastics film component 4 comprises an LC cell, and the temporary carrier 6 is replaced by another plastics film component 4 that provides one of two polarising filters on opposites sides of the LC cell.

The inventor for the present application has noticed an improvement in the processing yield when using a temporary carrier 6 between the plastics film component 4 and the vacuum stage 1. The inventor for the present application has attributed this improvement in processing yield to a reduction in the amount by which the edge portion (extending beyond the edge of the vacuum stage) of the plastics film component 4 deviates away from an X-Y plane parallel to the mounting surface of the vacuum stage, wherein the control of the processing based on the detected X-Y position of the alignment marks assumes that the edge portion of the plastics film component is parallel to the mounting surface of the vacuum stage 1.

FIG. 2 shows one example of a plastics film component for processing using the method described above, but the technique is equally applicable to other kinds of plastic film components for display and/or sensor devices. FIG. 3 shows the plastics film component of FIG. 2 after processing using the method described above.

In this example, the plastics film component 4 comprises a liquid crystal (LC) cell for processing before the application of polarising filters to opposite sides of the LC cell. With reference to FIG. 2, a stack 14 of conductor, semiconductor and insulator layers is formed in situ on a plastics support film 16. The stack 14 defines an array of pixel electrodes 18, and electrical circuitry for independently controlling each pixel electrode via conductors outside the array of pixel electrodes. The stack may, for example, define an active matrix array of thin-film transistors (e.g. OTFTs comprising an organic semiconductor channel), including: an array of gate conductors each providing the gate electrode for a respective row of TFTs, and extending to outside the array of pixel electrodes; and an array of source conductors each providing the source electrode for a respective column of TFTs, and extending to outside the array of pixel electrodes. Each pixel electrode is associated with a respective TFT, and each TFT is associated with a unique combination of gate and source conductors, whereby each pixel electrode can be addressed independently of all other pixels. A substantially uniform thickness of liquid crystal material 20 is contained between the array of pixel electrodes 18 and a counter component 22 comprising an array of colour filters supported on another plastics support film.

In this example, the processing using the vacuum stage mounting method described above may comprise bonding a chip-on-flex (COF) unit 24 to the edge portion of the support film 16 outside the array of pixel electrodes to create a conductive connection between (i) an array of conductors (e.g. source and gate addressing conductors) defined by the stack in a region outside the array of pixel electrodes and (ii) a corresponding array of conductors of the COF unit 24, which are connected to the terminals of one or more driver chips 26 forming part of the COF unit 24.

The LC cell includes alignment layers (e.g. rubbed polyimide layers) on both sides of the LC material to control the orientation of the LC director in the absence of an electric field generated by a potential difference between a pixel electrode and a counter electrode. The counter electrode may be on the same side of the liquid crystal material as the pixel electrode (such as in the case of a fringe field switching (FFS) device) or may be on the opposite side of the liquid crystal material to the pixel electrode (in which case, it may be constituted by a conductor layer forming part of the counter component 22 including the CFA array).

In this example, the plastics film component 4 is one of a set of plastics film components prepared by processing a larger area plastics film, and then dividing the processed plastics film into a plurality of individual plastics film components. With reference to FIG. 4, a large area plastics support film 100 is mounted on a temporary carrier 106 via an adhesive unit 108, and is processed in situ on the temporary carrier 106. As discussed above, the processing may comprise forming a stack of layers on the large area plastics support film that defines the above-described pixel electrode arrays 18 and addressing circuitry for a set of display/sensor devices. A second large area plastics support film (not shown) is also mounted on a second temporary carrier (not shown) via an adhesive unit (not shown), and is processed in situ on the temporary carrier to define a set of counter components 22 for the display/sensor devices within a large area plastics film component. These two large area, processed plastic film components are then brought together so as to contain LC material therebetween in at least the areas of the pixel electrode arrays 22. The resulting assembly is then released from the two temporary carriers, and divided into the individual plastics film components (having the relatively small profile 104) by e.g. laser or mechanical cutting. The temporary carrier used in the vacuum stage mounting described above is separate to the temporary carriers used in the preparation of the plastics film component 4 from large area plastics films; the individual plastics film component 4 is released from the temporary carrier(s) used for the preparation of the plastics film component 4 from large area plastics films, before mounting on the separate temporary carrier 6 described above for processing on the vacuum stage 1.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

What is claimed is:

1. A method comprising: preparing a self-supporting plastics film component comprising a plastics support film supporting at least a stack of layers defining an array of pixel electrodes and electrical circuitry for independently addressing each pixel electrode via conductors outside the array of pixel electrodes; thereafter attaching a carrier to the plastics film component; mounting the plastics film component via the carrier on a support unit surface defining a plurality of openings connected to a vacuum pump; and processing the plastics film component mounted on the support unit surface while operating the vacuum pump; and thereafter releasing the carrier from the plastics film component.

2. The method according to claim 1, wherein preparing the plastics film component comprises: forming at least part of the plastics film component by a process comprising attaching the support film via at least one layer of adhesive to another carrier; processing the support film in situ on the another carrier; and thereafter removing the support film from the another carrier.

3. The method according to claim 1, wherein processing the plastics film component comprises bonding a driver chip unit to the plastics film component, to create a conductive connection between an array of conductors of the plastics film component and a corresponding array of conductors of the driver chip unit.

4. The method according to claim 3, wherein the driver chip unit comprises a support film supporting said array of conductors of the driver chip unit, and at least one driver chip bonded to the support film with conductive connections between terminals of the driver chip and said array of conductors of the driver chip unit.

5. The method according to claim 1, wherein the carrier is more rigid than the plastics film component.

6. The method according to claim 1, wherein the carrier comprises a sheet of glass.

7. The method according to claim 1, wherein mounting the plastics film component on the vacuum stage comprises mounting the plastics film component such that an edge portion thereof extends beyond a lateral edge of the vacuum stage; and the processing comprises processing said edge portion of the plastics film component.
